(19) United States
(12) Patent Application Publication
(10) Pub. No.: US 2006/0098516 A1
(43) Pub. Date: May 11, 2006

(54) Semiconductor memory device

(75) Inventor: Seiji Nakashima, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/266,221

(22) Filed: Nov. 4, 2005

(30) Foreign Application Priority Data
Nov. 5, 2004 (JP) 322739/2004

(51) Int. Cl. G11C 8/00

(52) U.S. Cl. 365/230.03

(57) ABSTRACT

A semiconductor memory device includes: a plurality of memory cells, a plurality of word lines and a plurality of column selecting lines. The plurality of memory cells is configured to be arrayed in a matrix. The plurality of word lines is configured to extend in a first direction which is along one of a row direction and a column direction of said matrix. The plurality of column selecting lines is configured to extend in said first direction. A first memory cells of said plurality of memory cells are connected to the same one of said plurality of word lines. A second memory cells of said plurality of memory cells are connected to the same one of said plurality of column selecting lines. One of said plurality of memory cells is selected by one of said plurality of word lines and one of said plurality of column selecting lines.

### BACKGROUND OF THE INVENTION

1. Field of the Invention

The present invention relates to a semiconductor memory device, and in particular, relates to a semiconductor memory device that carries out writing and reading by charge and discharge of a bit line.

2. Description of the Related Art

In recent years, following a wide spread of portable devices represented by a portable phone, lowering of power consumption in a system LSI has been required with a necessity of extending a battery life. Further, as development of the system LSI is advanced, an amount of memory installed in a chip tends to be increased, and electric power consumed by a memory circuit in the chip accounts for a greater portion.

Japanese Laid Open Patent Application JP-A-Showa, 61-054097, Japanese Laid Open Patent Application JP-A-Heisei, 04-298887 and Japanese Laid Open Patent Application JP-A-Heisei, 05-109283 disclose a conventional technique for lowering of the electric power in the memory circuit (hereinafter, referred to as a conventional technique 1). FIG. 1 is a circuit diagram showing a configuration of the conventional technique 1 disclosed in the above-mentioned documents. In the conventional technique 1, as shown in FIG. 1, a memory circuit 100 includes memory cell circuits (M100, M101, . . . ); row address lines (RA0, RA1); column address lines (CA0, CA1, . . . ); word lines (WL00, WL10, . . . ); column selecting lines (CSL1, CSL2, . . . ); bit-line pairs (DT0, DB0, . . . ); logic circuits (RD00, RD10); and logic circuits (CD0, CD1, . . . ). The memory cell circuits (M100, M101, . . . ) are arrayed in a matrix of m rows by n columns (m and n are natural numbers). The word line selects the memory cell from the row side. The column selecting line selects the memory cell from the column side. The bit-line pair is connected to the memory cell circuit in a column direction. The logic circuit (RD) generates the word line signal based on the row address. The logic circuit (CD) generates the column selecting line signal based on the column address. The bit-line pair (DT0, DB0, . . . ) is connected to the memory cell circuit in a column direction.

FIG. 2 is a circuit diagram showing a detailed configuration of the memory cell circuit M100 used in the conventional technique 1. The plurality of memory cell circuits (M100˜M1mn) contained in the memory circuit 100 have the same configurations respectively. Therefore, the configuration of the memory cell circuit M100 will be described below. As shown in FIG. 2, the memory cell circuit M100 includes a data-storing unit 101 and an access transistor group 102. The data-storing unit 101 has a plurality of inverters. The input terminal of one inverter is connected to the output terminal of the other inverter. The access transistor group 102 is connected to the data-storing unit 101, and has two pairs of access transistors (111, 112, 121, 122). The one pair has the series-connected access transistors 111 and 112. The one end (access transistors 111) of the one pair is connected to the data-storing unit 101 and the other end (access transistors 112) is connected to the one (DT) of the bit-line pair (DT, DB). The other pair has the series-connected access transistors 121 and 122. The one end (access transistors 121) is connected to the data-storing unit 101 and the other end (access transistors 122) is connected to the one (DB) of the bit-line pair (DT, DB). The word line WL is connected to gates of the access transistor 111 and 121. The column selecting line CSL is connected to the gates of the access transistor 112 and 122.

Based on a row address signal and a column address signal, one word line and one column selecting line in the memory circuit 100 are respectively selected. Then, in the memory cell to which the selected word line and column selecting line are both connected, the access transistors 111, 112, 121 and 122 are on, and read and write operations are carried out for the memory cell. That is, when the word line WL00 and the column selecting line CSL0 are selected, only the memory cell circuit M100 is selected, and only the bit-line pair DT0, DB0 is operated.

Thus, by connecting the word line and the column selecting line to the access transistors in the memory cell, the number of the memory cell activated at the time of the operation is limited to one, to reduce power consumption caused by the charge and discharge of redundant bit-line pairs.

Also, Japanese Laid Open Patent Application JP-A-Heisei, 08-167291 discloses another conventional technique (hereinafter, referred to as conventional technique 2) for the lowering of the electric power in the memory circuit. The conventional technique 2 performs the lowering of the electric power by reducing the redundant bit-line pairs in which the charge and discharge is carried out at the time of the operation.

FIG. 3 is a circuit diagram showing a configuration of the conventional technique 2 disclosed in the above-mentioned document. In the conventional technique 2, as shown in FIG. 3, a memory circuit 200 includes memory cell circuits (M200, M201, . . . ); row address lines (RA0, RA1); column address lines (CA0, CA1, . . . ); word lines (WL00, WL01, . . . ); bit-line pairs (DT0, DB0, . . . ); and logic circuits (RD00, RD01, . . . ). The memory cell circuits (M200, M201, . . . ) are arrayed in a matrix of m rows by n columns (m and n are natural numbers). The word line selects the memory cell from the row side. The bit-line pair is connected to the memory cell circuit in a column direction. The logic circuit generates the word line signal based on the row address and the column address.

FIG. 4 is a circuit diagram showing a detailed configuration of the memory cell circuit M200 in the conventional technique 2. A plurality of memory cell circuits (M200˜M2mn) contained in the memory circuit 200 have the same configurations respectively. Therefore, the configuration of the memory cell circuit M200 is exemplified in FIG. 4. As shown in FIG. 4, the memory cell circuit M200 includes a data-storing unit 201 and access transistors 211, 221. The data-storing unit 201 has a plurality of inverters. The input terminal of one inverter is connected to the output terminal of the other inverter. The access transistor group 202 is connected to the data-storing unit 201, and has two access transistors (211, 221). The access transistors 211 is connected to the data-storing unit 101 and the one (DT) of the bit-line pair (DT, DB). The access transistors 221 is connected to the data-storing unit 201 and the one (DB) of the bit-line pair (DT, DB). The word line WL is connected to gates of the access transistors 211, 221 in the memory cell circuit M200.

Based on a row address signal and a column address signal, one word line in the memory circuit 200 is selected. Then, in the memory cell to which the selected word line is connected, the access transistors 211, 221 are on, and the read and write operations are carried out for the memory cell. That is, when the word line WL00 is selected, the memory cell M200, M201, M202, and M203 are selected, and the bit-line pairs DT0 and DB0, DT1 and DB1, DT2 and DB2, and DT3 and DB3 are operated.

Thus, to reduce the power consumption caused by the charge and discharge of the redundant bit-line pairs, the memory circuit 200 of a conventional type limits the number of the memory cells activated at the time of the operation by having a plurality of the word lines connected to the access transistor 211, 221 in the memory cell circuit (M2mn).

It has now been discovered that there are following problems in the conventional techniques 1 and 2. Regarding the conventional technique 1, an ordinary memory circuit does not read and write only one value of just one memory at one operation, but simultaneously carries out the reading and writing of data corresponding to a data width (the number of bits) processed in a CPU. Therefore, a configuration of the memory circuit that carries out data input and output of several bits, and signal lines that operates at the time of selecting the memory cell, are as shown in FIG. 5. FIG. 5 is a schematic view showing a configuration of a conventional memory circuit that carries out data input and output of several bits.

However, the conventional technique 1 is configured to be provided with the column selecting line for every bit, and the column selecting lines corresponding to the number of bits are operated at the time of the memory circuit being operated. As a result, the electric power consumed in the column selecting line is increased.

On the other hand, the conventional technique 2 is configured to have a plurality of the word lines. FIG. 6 is a circuit diagram showing another configuration of a conventional memory circuit of the conventional technique 2. As shown in FIG. 6, the power consumption can be most reduced with a configuration in which the same number of the word lines as the number of columns of a memory cell matrix, is provided. However, in order to realize this configuration, the word line is to be wired on the memory cell circuit in relation to a layout structure. As a result, an area of a memory cell region is increased due to the increase in the number of wiring lines.

FIG. 7 is a layout chart showing a layout of a conventional memory cell circuit. In FIG. 7, the access transistors 211, 221 are located on the upper part of the data-storing unit 201. For the purpose of reduction in the area, a poly wiring line common to an adjacent memory cell is used as a gate wiring line (the word line WL) in the access transistors. FIG. 8 is a circuit diagram showing a configuration of a conventional memory circuit related to the word line connections of the conventional technique 2. As shown in FIG. 8, the connection between a poly wiring line, which is a gate input of the access transistor, and a metal wiring line of the word line is carried out in a region of the connection cell T0, T1 arrayed in a constant space in a memory cell circuit portion. That is, in the conventional technique, a plurality of the word lines leads to the necessity of a plurality of the connection cell regions, resulting in the increase in the area.

Therefore, when two word lines are provided in view of the area reduction being prioritized, ½ of the bit-line pairs are operated and current reducing effect is ½ for one word line.

When the current reduction is prioritized, the number of the word lines has to be increased to result in the increase in the area. At the same time, signal wiring lines become longer in a memory cell array portion and a peripheral circuit portion, exemplified by the increase in a length of the bit-line pair corresponding to the increase in the number of the word lines. As a result, the power consumption is unexpectedly increased due to the increase in a capacitance of the signal wiring lines caused by the foregoing, and the effect corresponding to 1/(the number of the columns) in a simple calculation cannot be obtained. It is desired that a semiconductor memory device which both prevents the increase in the area of the memory cell region and realizes the low power consumption.

### SUMMARY OF THE INVENTION

In order to achieve an aspect of the present invention, the present invention provides a semiconductor memory device including: a plurality of memory cells configured to be arrayed in a matrix; a plurality of word lines configured to extend in a first direction which is along one of a row direction and a column direction of said matrix; and a plurality of column selecting lines configured to extend in said first direction, wherein a first memory cells of said plurality of memory cells are connected to the same one of said plurality of word lines, wherein a second memory cells of said plurality of memory cells are connected to the same one of said plurality of column selecting lines, wherein one of said plurality of memory cells is selected by one of said plurality of word lines and one of said plurality of column selecting lines.

In the present invention, only the selected memory cell, in which both the word line and the column selecting line are activated (selected), is activated. In this case, the read and write operations are carried out for the bit-line pair connected to the only selected memory cell, and are not carried out for the bit-line pair irrelevant to these operation. Therefore, the power consumption is suppressed in the bit-line pair in the column that is irrelevant to these operation. That is, the bit-line pair can be controlled by the combination of the word line and the column selecting line, and it is possible to obtain the low power consumption effect of 1/((the number of the word lines)×(the number of the column selecting lines)).

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram showing a configuration of the conventional technique 1;

FIG. 2 is a circuit diagram showing a detailed configuration of the memory cell circuit in the conventional technique 1;

FIG. 3 is a circuit diagram showing a configuration of the conventional technique 2;

FIG. 4 is a circuit diagram showing a detailed configuration of the memory cell circuit in the conventional technique 2;

FIG. 5 is a schematic view showing a configuration of a conventional memory circuit that carries out data input and output of several bits;

FIG. 6 is a circuit diagram showing another configuration of a conventional memory circuit of the conventional technique 2;

FIG. 7 is a layout chart showing a layout of a conventional memory cell circuit;

FIG. 8 is a circuit diagram showing a configuration of a conventional memory circuit related to the word line connections of the conventional technique 2;

FIG. 9A is a circuit diagram showing a configuration of a semiconductor memory device in a first embodiment according to the present invention;

FIG. 9B is a circuit diagram showing an example of a specific configuration of the first logic circuit of a semiconductor memory device in the first embodiment;

FIG. 9C is a circuit diagram showing an example of a specific configuration of the second logic circuit of a semiconductor memory device in the first embodiment;

FIG. 10 is a circuit diagram showing a detailed configuration of the memory cell circuit of a semiconductor memory device in the first embodiment;

FIG. 11 is a layout chart showing a layout of the memory cell circuit of a semiconductor memory device in the first embodiment;

FIG. 12 is a timing chart showing an operation of a semiconductor memory device in the first embodiment;

FIG. 13 is a schematic diagram showing a configuration of a memory circuit (semiconductor memory device) in the first embodiment;

FIG. 14 is a graph showing bit-number dependencies of current consumption of the first embodiment according to the present invention and conventional technique 1;

FIG. 15 is a circuit diagram exemplifying a configuration of a memory cell array including connection cells in the first embodiment;

FIG. 16 is a circuit diagram showing a configuration of a memory cell circuit in a second embodiment according to the present invention;

FIG. 17 is a table showing a size ratio of a single memory cell circuit used in the present invention and the conventional technique 2;

FIG. 18 is a table showing comparison of the area of the memory cell array and the power consumption between the present invention and the conventional technique 2;

FIG. 19A is graph showing the power consumption lowering effect when the numbers of the bit-line pairs to be activated in the present invention and the conventional technique 2 are made equal;

FIG. 19B is graph showing the memory cell area when the numbers of the bit-line pairs to be activated in the present invention and the conventional technique 2 are made equal; and

FIG. 20 is a flowchart showing an read and write operation in the first embodiment.

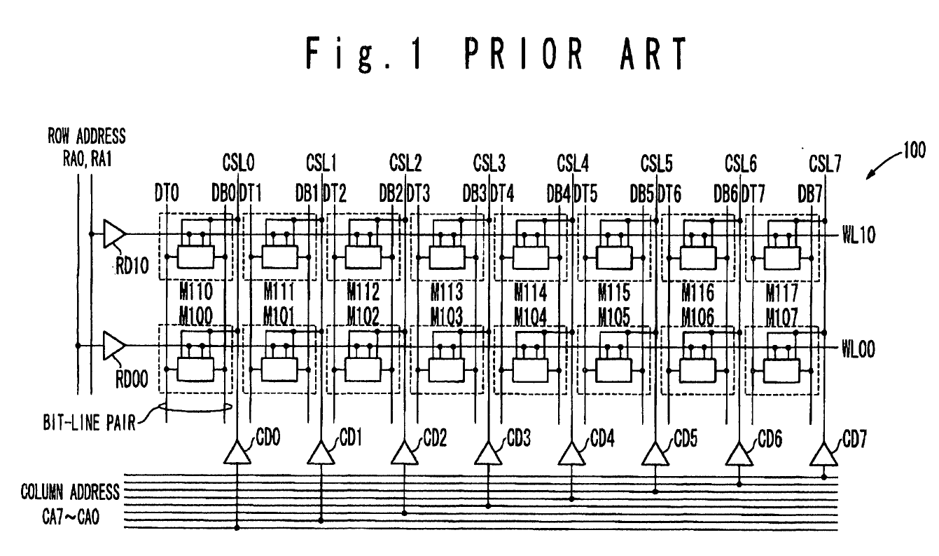

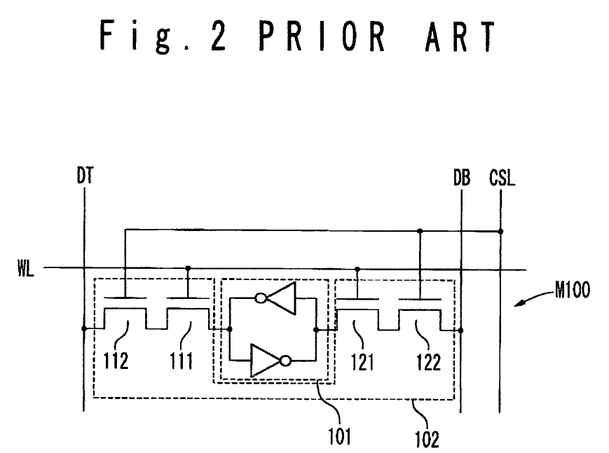

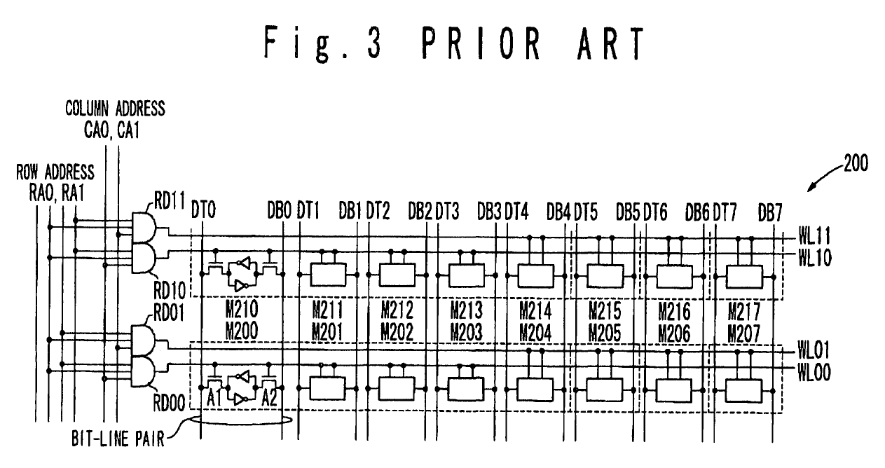

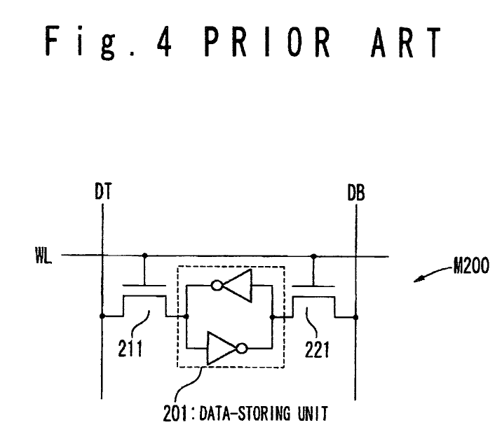

### DESCRIPTION OF THE PREFERRED EMBODIMENTS

### A First Embodiment

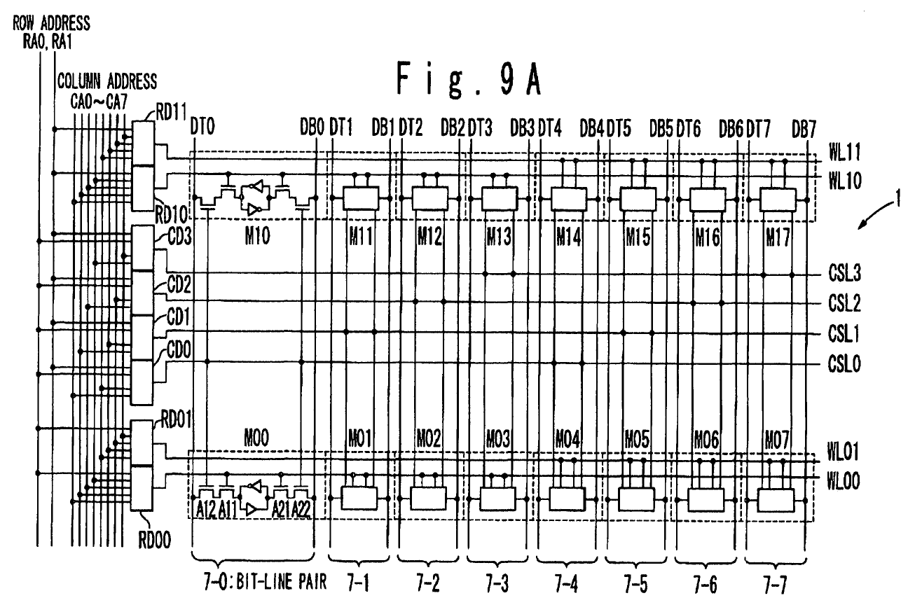

Embodiments of the semiconductor memory device according to the present invention will be described below with reference to the attached drawings. FIG. 9A is a circuit diagram showing a configuration of a semiconductor memory device in a first embodiment according to the present invention. As shown in FIG. 9A, the semiconductor memory device (the memory circuit 1) in this embodiment includes memory cell circuits (M00, M01, . . . ); row address lines (RA0, RA1); column address lines (CA0, CA1, . . . ); word lines (WL00, WL01, . . . ); column selecting lines (CSL0, CSL1, . . . ); bit-line pairs 7-n (DT0_DB0, DT1_DB1, . . . ); first logic circuits (RD00, RD01, . . . ); and second logic circuits (CD0, CD1, . . . ). The memory cell circuits (M00, M01, . . . ) are arrayed in a matrix of (m+1) rows by (n+1) columns (m and n are integer, equal to or more than zero), and have two series-connected access transistors and a data-storing unit therebetween. The row address lines (RA0, RA1) supplies row addresses of the memory circuit 1. The column address lines (CA0, CA1, . . . ) supplies column addresses of the memory circuit 1. The word line (WL00, WL01, . . . ) selects at lease one of the memory cells from the row side. The column selecting lines (CSL0, CSL1, . . . ) selects at lease one of the memory cells from the column side. The bit-line pairs 7-n (DT0_DB0, DT1_DB1, . . . ) are connected to the memory cell circuits in a column direction. The first logic circuits (RD00, RD01, . . . ) drives the word line in response to a row address signal and a column address signal. The second logic circuits (CD0, CD1, . . . ) drives the column selecting line (CSL0, CSL1, . . . ) in response to the row address signal and the column address signal.

Incidentally, although a memory circuit 1 shown in FIG. 9A is a circuit of an eight-column configuration having a plurality of memory cell circuits (M00 to M07, M10 to M17), this does not limit a configuration of a memory circuit to which the present invention is applied. Further, explanation is given with the use of a reference mark with a numeral, only when the memory cell circuits; row address lines; column address lines; word lines; column selecting lines; bit-line pairs; first logic circuits; and second logic circuits needs to be distinguished individually. As for each signal line (the word line, the bit-line pair, and so on) with the reference mark but without a numeral, this signal line is arbitrary one.

FIG. 9B is a circuit diagram showing an example of a specific configuration of the first logic circuit (RD00, RD01, . . . ) of a semiconductor memory device in the first embodiment. Since a plurality of the first logic circuits (RD00, RD01, . . . ) have the same configurations, description thereof is given in correspondence to the first logic circuit RD11. The first logic circuit RD11 includes an OR circuit and an AND circuit. As shown in FIG. 9B, each of input terminals of this OR circuit is connected to corresponding one of the row address lines CA4 to CA7. One of input terminals of this AND circuit is connected to the row address line RA1, and another is connected to the output terminal of the AND circuit. With this configuration, the first logic circuit RD11 drives the word line WL11, based on the column address signal supplied from the column address lines CA4 to CA7, and the row address signal supplied from the row address line RA1.

FIG. 9C is a circuit diagram showing an example of a specific configuration of the second logic circuit (CD00, CD01, . . . ) of a semiconductor memory device in the first embodiment. Since a plurality of the second logic circuits (CD0, CD1, . . . ) have the same configurations, description thereof is given in correspondence to the second logic circuit CD3. The second logic circuit CD3 includes a first OR circuit; a second OR circuit; and an AND circuit. As shown in FIG. 9C, one of input terminals of the first OR circuit is connected to the row address line RA0, and another is connected to the row address line RA1. One of input terminals of the second OR circuit is connected to the column address line CA4, and another is connected to the column address line CA7. One of input terminal of the AND circuit is connected to an output terminal of the first OR circuit, and another is connected to an output terminal of the second OR circuit. With this configuration, the second logic circuit CD3 drives the column selecting line CSL3, based on the column address signal supplied from the column address lines CA4 and CA7, and the row address signal supplied from the row address lines RA0 and RA1.

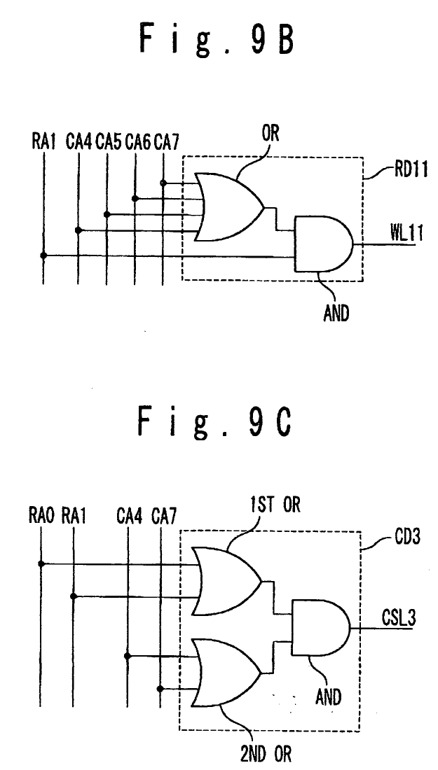

FIG. 10 is a circuit diagram showing a detailed configuration of the memory cell circuit of a semiconductor memory device in the first embodiment. Since a plurality of the memory cell circuits has the same configurations respectively, description thereof is given below in correspondence to the memory cell M00. As shown in FIG. 10, the memory cell circuit M100 includes a data-storing unit 2 and an access transistor group 3. The data-storing unit 2 has a plurality of inverters. The input terminal of one inverter is connected to the output terminal of the other inverter. The access transistor group 3 is connected to the data-storing unit 2, and has two transistor pairs of access transistors (A11, A12, A21, and A22). The first transistor pair 4 has a first and third access transistors A11 and A21. The gates of the first and third access transistors A11 and A21 are connected to the node N11 and N21 of the word line WL, respectively. The second transistor pair 5 has a second and fourth access transistors A12 and A22. The gates of the second and fourth access transistors A12 and A22 are connected to the node N12 and N22 of the column selecting line CSL, respectively. The first and second access transistors are series-connected to each other, of which one end (first access transistors A11) is connected to the data-storing unit 2 and another end (second access transistors A12) is connected to at a node N13 of a bit line DT of the bit-line pair (DT, DB). The third and fourth access transistors are series-connected to each other, of which one end (third access transistors A21) is connected to the data-storing unit 2 and another end (fourth access transistors 22) is connected to at a node N23 of a bit line DB of the bit-line pair (DT, DB).

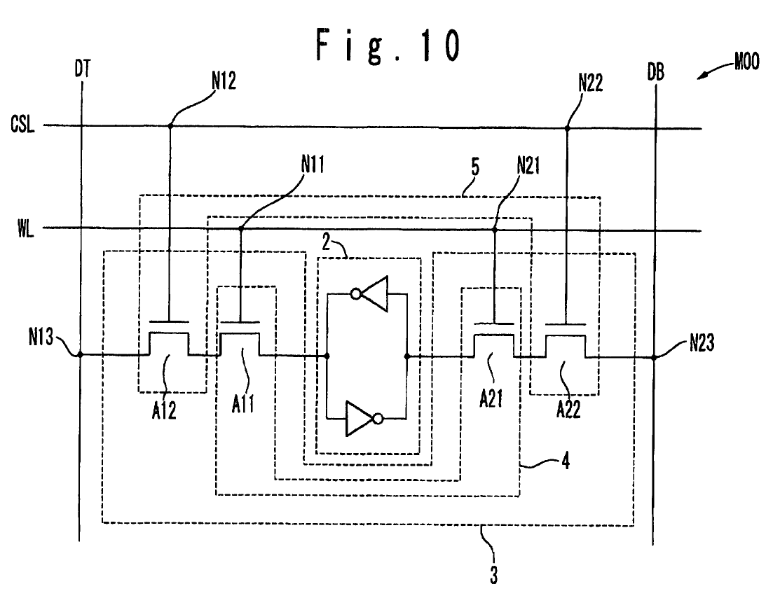

FIG. 11 is a layout chart showing a layout of the memory cell circuit M00 of a semiconductor memory device in the first embodiment. As shown in FIG. 11, in the memory cell circuit Mmn of the first embodiment, the first access transistor pair 4 (a pair of the first access transistor A11 and the third access transistor A21) is placed on the upper part of the data-storing unit 2. The second access transistor pair 5 (a pair of the second access transistor A12 and the fourth access transistor A22) is placed on the upper part of the first access transistor pair 4. In the first embodiment, the memory circuit 1 arrays the column selecting line CSL in a row direction. For this reason, it is possible for two adjacent upper and lower cells in the column direction, to have the common column selecting line CSL. That is, it is possible to provide one column selecting line CSL between facing two memory cell circuits Mmn, and to configure the column selecting line CSL to be connected to each of the two memory cell circuits. Therefore, the column selecting line CSL is configured to pass through on the series-connected access transistors, to suppress the increase in the chip area.

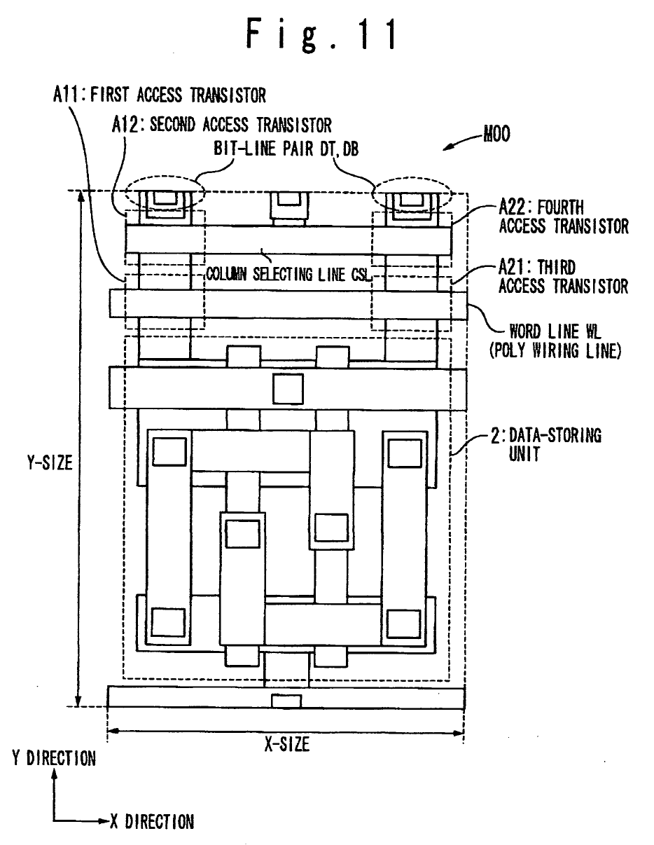

Next, the operation of a semiconductor memory device in the first embodiment will be described with reference to FIG. 9A to 12. FIG. 12 is a timing chart showing an operation of a semiconductor memory device in the first embodiment. FIG. 12 (a) exemplifies the operations of the row address lines (RA0, RA1). FIG. 12 (b) exemplifies the operations of the column address lines (CA0 to CA7). FIG. 12 (c) exemplifies the operations of the word lines (WL11, WL10). FIG. 12 (d) exemplifies the operations of the column selecting lines (CLS0 to CLS3). FIG. 12 (e) exemplifies the operations of the word line (WL00, WL001).

As shown in FIG. 12, if selected row addresses (RA0, RA1), and selected column addresses (CA0, CA1, . . . , CAn) are activated (supplied) (=High level) (step S01), one of the first logic circuits (RD00, RD01, . . . ) and one of the second logic circuits (CD0, CD1, . . . ) are selected. Then, the first access transistor pair 4 and the second access transistor pair 5 in a selected memory cell circuit (M00, M01, . . . , Mmn), which is selected by the selected first logic circuit (RD00, RD01, . . . ) and second logic circuit (CD0, CD1, . . . ), are activated (step S02). At this time, discharge of the bit-line pair 7-i (i=0 to n) is started based on the data stored in the memory cell circuit in the read operation (step S03), or the data is written for the memory cell based on a potential of the bit-line pair 7-n in the write operation (step S03).

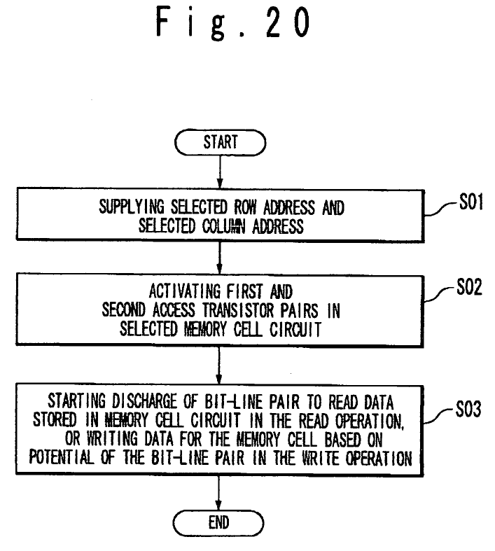

For example, the operation for the memory cell circuit M00 is as follows. In a period from the time t1 to t2, since the row address RA0 and the column address CA0 are activated (S01), the first logic circuits RD00 and the second logic circuits CD0 are selected. Then, the access transistor group 3 in the memory cell circuit M00, which is selected by the selected first logic circuit RD00 and second logic circuit CD0, is activated (S02). At this time, discharge of the bit-line pair 7-0 is started based on the data stored in the memory cell in the read operation (S03), or the data is written for the memory cell based on a potential of the bit-line pair 7-0 in the write operation (S03). FIG. 20 is a flowchart showing an read and write operation in the first embodiment.

In the configuration of the first embodiment, the first access transistor pair 4 is activated but the second access transistor pair 5 is deactivated in an unselected memory cell circuit, in which the word line WL is activated and the column selecting line CSL is deactivated (=Low level). For this reason, the unselected memory cell circuit (M00 to Mmn excluding selected memory cell circuit) does not supply the stored data to the bit-line pair (7-0 to 7-n) in the read operation. Similarly, a write data is not written to the unselected memory cell circuit (M00 to Mmn excluding selected memory cell circuit) in the write operation, even if the write data is supplied to the respective bit-line pair.

Also, in the unselected memory cell circuit (M00 to Mmn excluding selected memory cell circuit) in which the word line WL is deactivated and the column selecting line CSL is activated, the first access transistor pair 4 is deactivated though the second access transistor pair 5 is activated. For this reason, the unselected memory cell circuit (M00 to Mmn excluding selected memory cell circuit) does not supply the memory cell data to the bit-line pairs (7-0 to 7-n excluding the bit-line pair for the selected memory cell circuit) in the read operation. Similarly, a write data is not written to the unselected memory cell circuit in the write operation.

Similarly, even when both the word line WL and the column selecting line CSL are deactivated, the first access transistor pair 4 and the second access transistor pair 5 are deactivated. Therefore, the unselected memory cell circuit (M00 to Mmn excluding selected memory cell circuit) does not supply the memory cell data to the bit-line pair 7-i in the read operation. In the same way, a write data is not written to the unselected memory cell circuit in the write operation.

In the first embodiment, since only the selected memory cell circuit (M00 to Mmn), in which both the word line WL and the column selecting line CSL is activated, is activated, the bit-line pair 7-i in which the charge and discharge is carried out, can be controlled by the combination of the word line WL and the column selecting line CSL. Therefore, it is possible to obtain the low power consumption effect of 1/((the number of the word lines)×(the number of the column selecting lines)).

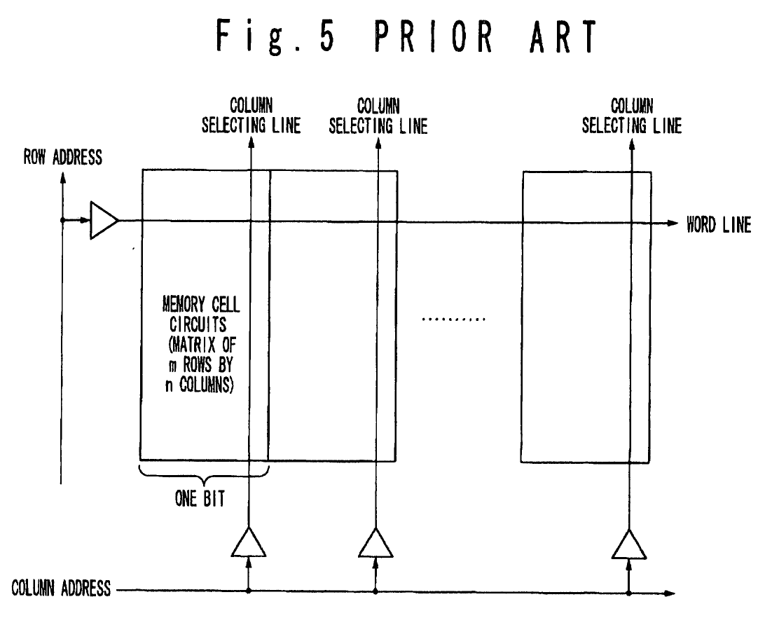

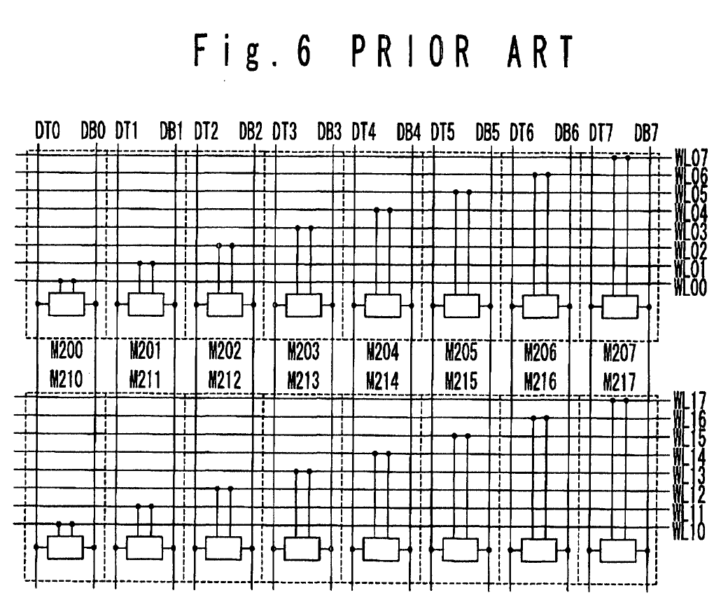

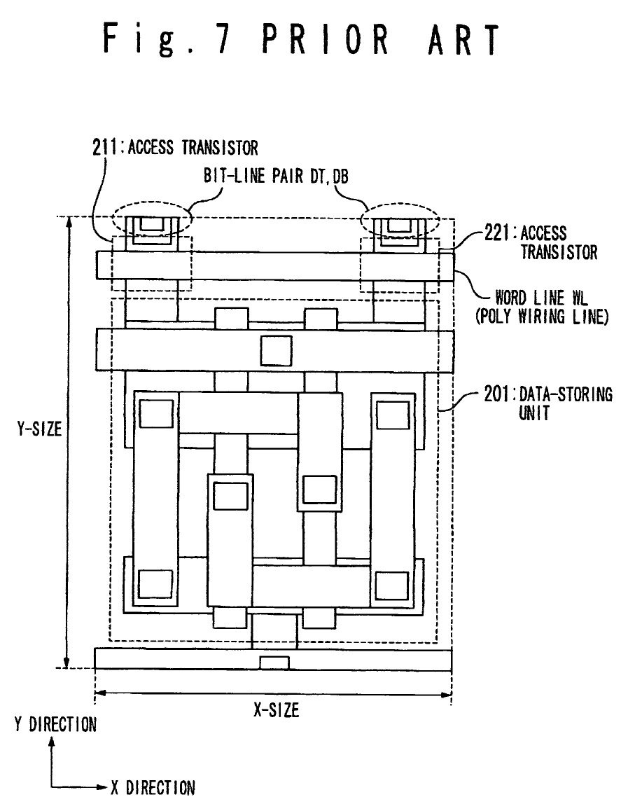

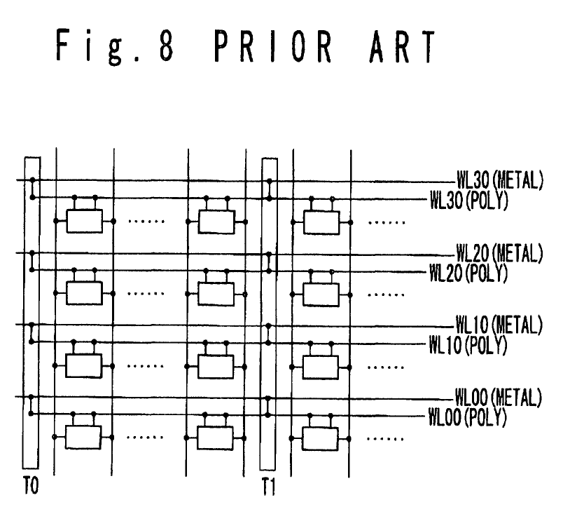

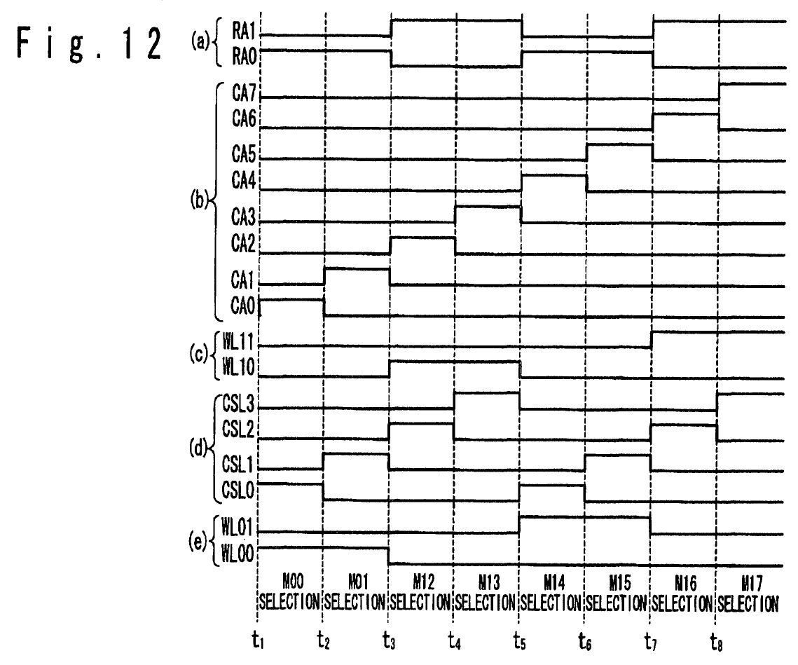

FIG. 13 is a schematic diagram showing a configuration of a memory circuit (semiconductor memory device) in the first embodiment. In this case, the memory circuit is used for a memory circuit that carries out the data input and output of several bits. Here, pathways, in which signals pass through at the time of the operation selecting the memory cell circuit, is shown in FIG. 13. With reference to FIG. 13, difference in the present invention and the conventional technique 1 lies in wiring directions of the column address line and the column selecting line. It is shown that there is a difference in the number of the signal wiring lines to be operated, in the circuit shown in FIG. 13 and that of the conventional technique 1 shown in FIG. 5.

Here, the capacitance of the signal line to be operated is indicated by a formula (1) as described below. Here, the memory cell circuits are arrayed in the matrix of m rows by n columns, an X-size and a Y-size of are X and Y respectively, the bit width (the number of bits) of data that the memory circuit inputs and outputs is B, and unit capacitance of the signal line is Cwire. For the sake of comparison, the capacitance in the case of the conventional technique 1 is indicated by a formula (2) as described below. Here, definition of the X-size and the Y-size is given with reference to FIG. 11. In coordinate axes shown in FIG. 11, the X-size is a size in an X-axis direction of the memory cell circuit, and the Y-size is a size in an Y-axis direction of the memory cell circuit.

$$\begin{matrix}\{ ( Y \times m \times 1 ) + ( X \times n \times B ) + ( Y \times m \times 1 ) + ( X \times n \times B ) \} \times Cwire = ( X \times n \times B \times Cwire ) \times 2 + Y \times m \times Cwire \times 2 & ( 1 ) \\ \{ ( Y \times m \times 1 ) + ( X \times n \times B ) + ( X \times n \times B ) + ( Y \times m \times B ) \} \times Cwire = ( X \times n \times B \times Cwire ) \times 2 + Y \times m \times Cwire \times ( B + 1 ) & ( 2 )\end{matrix}$$

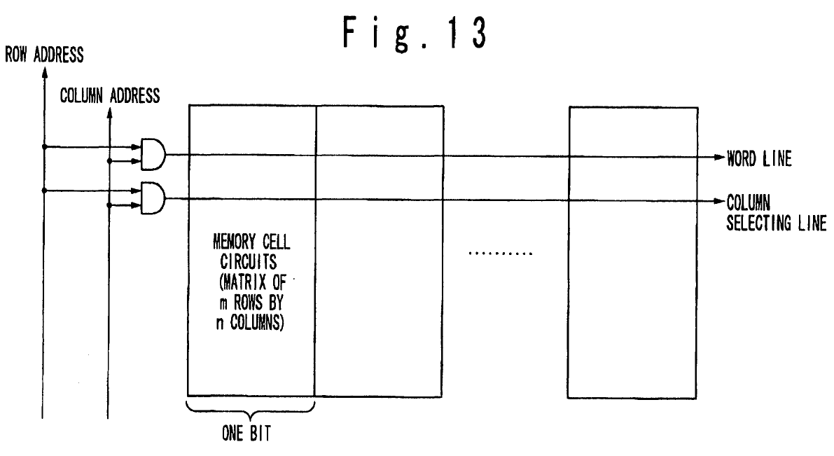

Here, each term shown in { } in the formula (1) is explained. The first term (Y×m×1) shows the capacitance of the row address line while 1 shows one signal line. The second term (X×n×B) shows the capacitance of the word line. The third term (Y×m×1) shows the capacitance of the column address line. Finally, the fourth term (X×n×B) shows the capacitance of the column selecting line. In the same way, each term shown in { } in the formula (2) is explained. The first term (Y×m×1) shows the capacitance of the row address line. The second term (X×n×B) shows the capacitance of the word line. The third term (X×n×B) shows the capacitance of the column address line. Finally, the fourth term (Y×m×B) shows the capacitance of the column selecting line. The results are shown in FIG. 14.

FIG. 14 is a graph showing bit-number dependencies of current consumption of the first embodiment of the present invention and conventional technique 1. A vertical axis (current Idd) indicates a current flowing in a bit-line pair, and a horizontal axis indicates a number of bits (bit-number). G2 and G1 indicates the bit-number (number of bits) dependencies in the embodiment of the present invention and the conventional technique 1, respectively. The present invention has less total capacitance of the wiring line to be operated, which is clearly effective for the lowering of the power consumption (total currents).

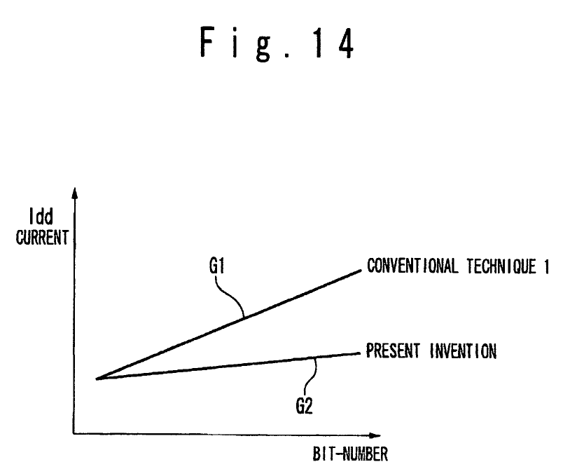

Next, the current consumption of the first embodiment and the conventional technique 2 are mentioned below. Firstly, an image of memory cell array in the case that one pair of bit-line pair is activated by applying the present invention for the memory cell circuit of the eight-column configuration, is shown in FIG. 15. FIG. 15 is a circuit diagram exemplifying a configuration of a memory cell array including connection cells in the first embodiment of the present invention. In the conventional technique 2, the number of bit-line pairs activated at the operation of the memory circuit is: “(the number of the memory cell columns)/(the number of the word lines)”. On the other hand, in the present invention, that number is: “(the number of the memory cell columns)/((the number of the word lines)×(the number of the column selecting lines))”.

Further, two adjacent upper and lower cells can have the common column selecting line in the present invention. Therefore, the present invention can make the number of the activated bit-line pairs fewer equal, with the fewer number of the wiring lines. Also, since the number of the word lines are decreased, it is possible to reduce the region of the connection cell (T0, T1) that carries out the connection of the metal wiring and the poly wiring of the word line.

As a result of the foregoing, use of the embodiment makes it possible to control the increase in the area of the memory cell array more than the conventional technique 2.

Here, the electric current consumed in the memory cell array per bit is divided into that of the word line and a column selecting signal line. Part of the consumed electric current is a current flowing in the word line, which is the signal line to the X direction. Another part of the consumed electric current is a charge and discharge current of wiring capacitance of the bit-line pair, which is the signal line to the Y direction. The charge and discharge current is indicated by a formula (3) as described below. Here, the X-size of the memory cell is X, the X-size of the connection cell is XT, the unit capacitance of the signal wiring line is Cwire, amplitude of the bit-line pair is ΔV, and power supply voltage is VDD.
Idd={X×n+XT×(the number of necessary connection cells)}×Cwire}×VDD×the number of actuating signals+{(Y×m)×Cwire}×ΔV×the number of the activated bit-line pairs (3)

Regarding the charge and discharge current to the X direction, the number of the actuating signals is one, which is the word line, in the conventional technique 2, while that number is two, which are the word line and the column selecting line, in the present invention. However, the number of the connection cells necessary is equal to the number of the word lines Therefore, when one pair of the bit-line pair is activated in the eight-column configuration, the number of the connection cells necessary is eight and two in the conventional technique 2 and the first embodiment, respectively. At this time, if XT is approximately equal to X/2,

$$\begin{matrix}\begin{matrix}Idd in the X direction of \\ the conventional technique\end{matrix} = \{ ( X \times 8 + XT \times 8 ) \times Cwire \} \times \\ VDD \times 1 line \\ = 12 X \times Cwire \times VDD\end{matrix}$$

$$\begin{matrix}\begin{matrix}Idd in the X direction of \\ the present invention\end{matrix} = \{ ( X \times 8 + XT \times 2 ) \times Cwire \} \times \\ VDD \times 2 lines \\ = 18 X \times Cwire \times VDD\end{matrix}$$

Thus, the current consumption in the X direction in the first embodiment is approximately half as much again (18/12) as in the conventional technique.

Regarding the charge and discharge current to the Y direction of one pair of the bit-line pair on the other hand, while the number of passing wiring lines (word lines) in the row direction is eight in the conventional technique 2, that number is four in the first embodiment. These four passing wiring lines are the column selecting lines shared by the adjacent upper and lower memory cell circuits. Consequently, it is possible to halve a wiring region to four lines even if two word lines are included. Then, the length in the Y direction of the bit-line pair can be shortened. On the other hand, considering that the number of the transistor are increased by two per cell compared with the conventional technique 2, the current consumption in the Y direction of the embodiment is increased by 0.6 times compared with the conventional technique, which means that the charge and discharge current in the Y direction can be reduced than in the conventional technique 2.

Here, the size of the memory cell array per bit is a variable determined by the number of the memory cell columns and the number of the word lines in the cases of the X direction and the Y direction, respectively. Therefore, it is clear that a region as indicated by the following is definitely present:
the decrease in the current consumption in the Y direction>the increase in the current consumption in the X direction
As a result of the foregoing, the present invention realizes the effect that is not realized in the conventional techniques 1 and 2. The present invention therefore, is effective as a power consumption lowering technique.

### A Second Embodiment

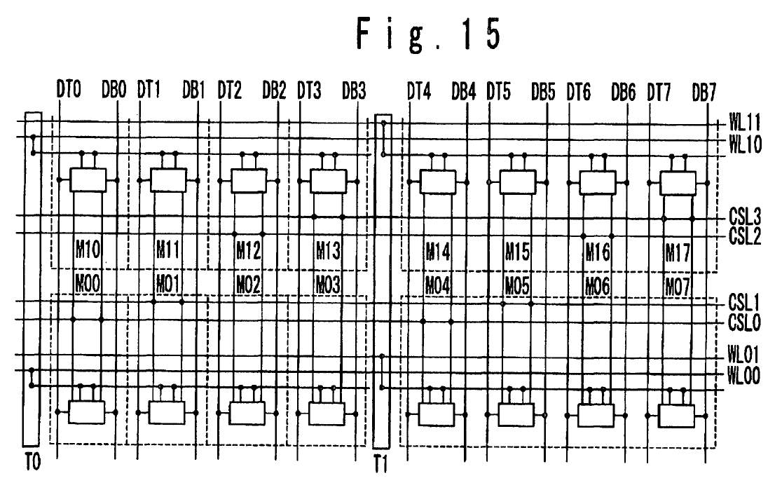

FIG. 16 is a circuit diagram showing a configuration of a memory cell circuit in a second embodiment according to the present invention. In this case, a combination of the number of the word lines and that of the column selecting lines is changed in the second embodiment. In an explanation of the embodiment below, the same part as that in the first embodiment regarding configurations and operation, are not explained.

As shown in FIG. 16, a circuit in the second embodiment appropriately combines the numbers of the word lines and the column selecting lines in accordance with a configuration of the column number of the memory cell arrangement, in order to control the number of the bit-line pairs activated at the operation.

It is clear that the second embodiment has the same power consumption lowering effect as the first embodiment compared with the conventional technique 1. Effect compared with the conventional technique 2 is mentioned below.

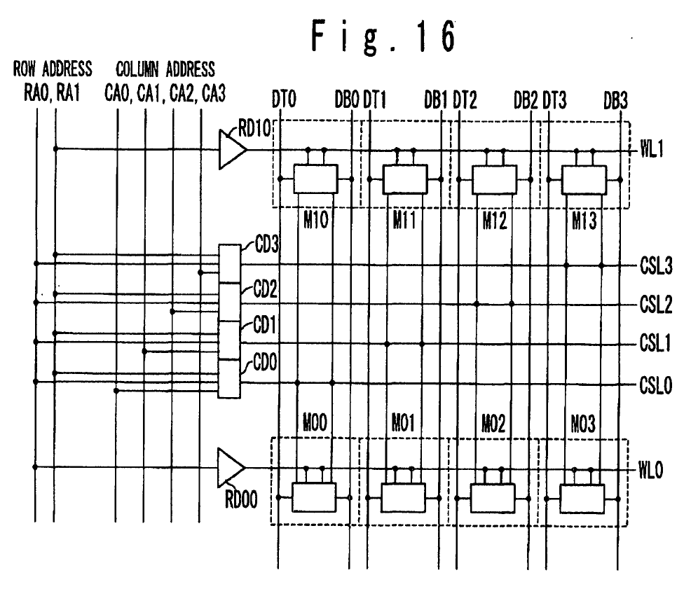

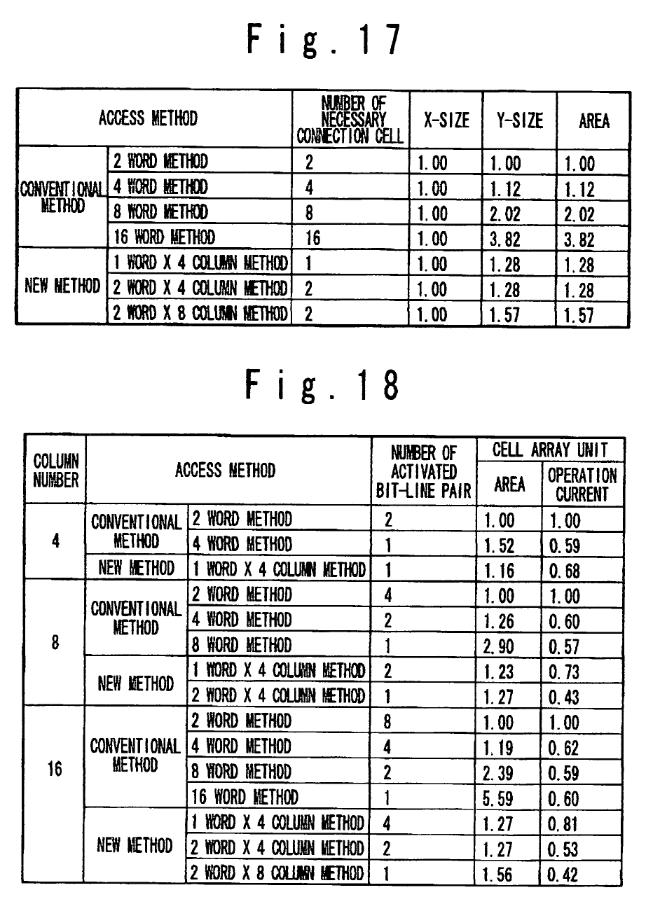

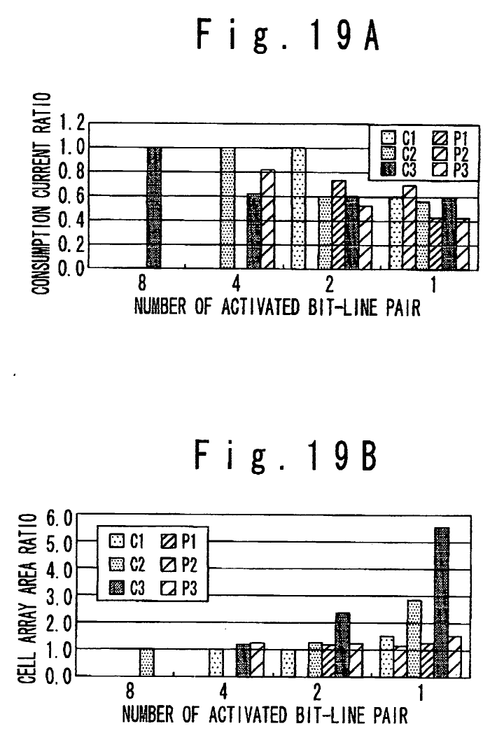

FIG. 17 is a table showing a size ratio of a single memory cell circuit used in the present invention and the conventional technique 2. For example, a 2 word method means a method to use two word lines for a memory cell column, and a 4 column method means a method to use four column selecting lines for a memory cell column. FIG. 18 is a table showing comparison of the area of the memory cell array and the power consumption between the present invention and the conventional technique 2. Here, in the present invention, the word line and the column selecting line are combined to be controlled. In the conventional technique 2, the number of the bit-line pairs to be activated is controlled. The number of columns mentioned in FIG. 18 is a number of columns “n”. This table indicates the comparison of the effect on lowering electric power consumption per 1024 cell×1 bit. Also, FIGS. 19A and 19B are graphs showing the power consumption lowering effect and the memory cell area, respectively, when the numbers of the bit-line pairs to be activated in the present invention and the conventional technique 2 are made equal. In FIGS. 19A and 19B, the symbol “C1” indicates a 4-column configuration of a conventional method. The symbol “C2” indicates a 8-column configuration of a conventional method. The symbol “C3” indicates a 16-column configuration of a conventional method. The symbol “P1” indicates a 4-column configuration of a new method of the present invention. The symbol “P2” indicates a 8-column configuration of a new method of the present invention. The symbol “P3” indicates a 16-column configuration of a new method of the present invention. The 4-column configuration means that the memory cell circuits in the adjacent 4 columns (and the same row) are connected to the same word line as shown in FIG. 9A.

As shown in FIGS. 17, 18, 19A and 19B, in the methods of the conventional technique 2, fewer the number of the bit-line pairs to be activated is, the greater the area of a cell array becomes. Then, the power consumption lowering effect remains flat, though the number of the activated bit-line pairs is reduced. In the methods of the present invention on the other hand, the increase in the area is much lower even if the number of the activated bit-line pairs is reduced. Therefore, the power consumption lowering effect corresponding to the reduction in the number of the activated bit-line pairs can be obtained, which means that the present invention is effective as the power consumption lowering technique.

As described above, the present invention makes it possible to configure a circuit that suppresses the power consumption in the bit-line pair in the column that is irrelevant to the operation. That is, the memory circuit of the present invention suppresses the electric power unnecessarily consumed in the bit-line pair in an ordinary memory circuit of a conventional type. Also, the memory circuit of the present invention has a fewer number of the column selecting lines to be operated, compared with the conventional technique 1. Therefore, the total capacitance of the wiring line to be operated can be reduced, and the electric power consumed in the signal line can then be reduced. Also, the present invention makes it possible to configure a memory circuit having the power consumption lowering effect while suppressing the increase in the area, compared with the case that the power consumption lowering effect equal to the conventional technique 2, is to be obtained. Further, the increase in the area when the power consumption lowering effect is made larger, is smaller in the present invention compared with the conventional technique 2. Consequently, it is possible to configure a circuit that has a low reduction rate of the power consumption lowering effect caused by the increase in the capacitance of the signal wiring line.

That is, according to the present invention, in the memory circuit, it is possible to reduce the electric power unnecessarily consumed in the bit-line pair in the column that is irrelevant to the operation. In addition, the memory circuit can be formed with a fewer number of the column selecting lines. Consequently, a total capacitance of the wiring lines to be operated can be reduced, and the electric power consumed in the signal lines can then be reduced. Also, when low power consumption effect is to be obtained to the same degree with the conventional memory circuit, it is possible to configure a circuit of the low power consumption with the increase in the area being prevented. Further, since the increase in the area is small when the low power consumption effect is increased, it is possible to configure a memory circuit that has a low reduction rate in the low power consumption effect caused by the increase in the capacitance of the signal wiring lines.

It is apparent that the present invention is not limited to the above embodiment, that may be modified and changed without departing form the scope and spirit of the invention.

What is claimed is:

1. A semiconductor memory device comprising:
a plurality of memory cells configured to be arrayed in a matrix;
a plurality of word lines configured to extend in a first direction which is along one of a row direction and a column direction of said matrix; and
a plurality of column selecting lines configured to extend in said first direction,
wherein a first memory cells of said plurality of memory cells are connected to the same one of said plurality of word lines,
wherein a second memory cells of said plurality of memory cells are connected to the same one of said plurality of column selecting lines, and
wherein one of said plurality of memory cells is selected by one of said plurality of word lines and one of said plurality of column selecting lines.

2. The semiconductor memory device according to claim 1, wherein said plurality of column selecting lines outputs a column selecting signal which is logically generated such that 1/n (n is an integer more than 1) memory cells of said first memory cells is activated.

3. The semiconductor memory device according to claim 1, wherein each of said plurality of memory cells includes:
a data storing unit configured to store a data,
a first transistor configured to be connected between said data storing unit and a first bit line, wherein a gate of said first transistor is connected to a corresponding one of said plurality of word lines as a first word line, and
a second transistor configured to be connected between said first transistor and said first bit line, wherein a gate of said second transistor is connected to a corresponding one of said plurality of column selecting lines as a first column selecting line.

4. The semiconductor memory device according to claim 3, wherein said each of the plurality of memory cells further includes:
a third transistor configured to be connected between said data storing unit and a second bit line, wherein a gate of said third transistor is connected to said first word line, and
a fourth transistor configured to be connected between said third transistor and said second bit line, wherein a gate of said fourth transistor is connected to said first column selecting line.
wherein said first bit line and said second bit line are set as a pair.

5. The semiconductor memory device according to claim 1, wherein each of said plurality of column selecting lines is provided between two adjacent memory cells of said plurality of memory cells, and supplies a column selecting signal to each of said two adjacent memory cells.

6. The semiconductor memory device according to claim 1, further comprising:
a first logic circuit configured to select one of said plurality of word lines based on a row address and a column address; and
a second logic circuit configured to select one of said plurality of column selecting lines based on said row address and said column address,
wherein said first logic circuit outputs a word signal to said one of the plurality of word lines, and
wherein said second logic circuit outputs a column selecting signal to said one of the plurality of column selecting lines.

7. The semiconductor memory device according to claim 2, wherein each of said plurality of memory cells includes:
a data storing unit configured to store a data,
a first transistor configured to be connected between said data storing unit and a first bit line, wherein a gate of said first transistor is connected to a corresponding one of said plurality of word lines as a first word line, and
a second transistor configured to be connected between said first transistor and said first bit line, wherein a gate of said second transistor is connected to a corresponding one of said plurality of column selecting lines as a first column selecting line.

8. The semiconductor memory device according to claim 2, wherein each of said plurality of column selecting lines is provided between two adjacent memory cells of said plurality of memory cells, and supplies a column selecting signal to each of said two adjacent memory cells.

9. The semiconductor memory device according to claim 2, further comprising:
a first logic circuit configured to select one of said plurality of word lines based on a row address and a column address; and
a second logic circuit configured to select one of said plurality of column selecting lines based on said row address and said column address,
wherein said first logic circuit outputs a word signal to said one of the plurality of word lines, and
wherein said second logic circuit outputs a column selecting signal to said one of the plurality of column selecting lines.

10. The semiconductor memory device according to claim 7, wherein each of said plurality of column selecting lines is provided between two adjacent memory cells of said plurality of memory cells, and supplies a column selecting signal to each of said two adjacent memory cells.

11. The semiconductor memory device according to claim 7, further comprising:
a first logic circuit configured to select one of said plurality of word lines based on a row address and a column address; and
a second logic circuit configured to select one of said plurality of column selecting lines based on said row address and said column address,
wherein said first logic circuit outputs a word signal to said one of the plurality of word lines, and
wherein said second logic circuit outputs a column selecting signal to said one of the plurality of column selecting lines.

12. A method for operating a semiconductor memory device, wherein said semiconductor memory device including:
a plurality of memory cells configured to be arrayed in a matrix;
a plurality of word lines configured to extend in a first direction which is along one of a row direction and a column direction of said matrix; and
a plurality of column selecting lines configured to extend in said first direction,
wherein a first memory cells of said plurality of memory cells are connected to the same one of said plurality of word lines, and
wherein a second memory cells of said plurality of memory cells are connected to the same one of said plurality of column selecting lines,
said method comprising:
(a) selecting one of said plurality of word lines and one of said plurality of column selecting lines based on a row address and a column address;
(b) selecting one of plurality of memory cells based on said selected one of the plurality of word lines and said selected one of the plurality of column selecting lines; and
(c) executing one of a read operation and a write operation on said selected one of the plurality of memory cells.

13. The method for operating a semiconductor memory device according to claim 12, wherein said step (b) includes:
(b1) outputting a column selecting signal to said selected one memory cell through said selected one column selecting line,
wherein said column selecting signal logically generated such that 1/n (n is an integer more than 1) memory cells of said first memory cells is activated.

14. The method for operating a semiconductor memory device according to claim 12, wherein each of said plurality of memory cells includes:
a data storing unit configured to store a data,
a first transistor configured to be connected between said data storing unit and a first bit line, wherein a gate of said first transistor is connected to a corresponding one of said plurality of word lines as a first word line, and
a second transistor configured to be connected between said first transistor and said first bit line, wherein a gate of said second transistor is connected to a corresponding one of said plurality of column selecting lines as a first column selecting line.

15. The method for operating a semiconductor memory device according to claim 14, wherein said each of the plurality of memory cells further includes:
a third transistor configured to be connected between said data storing unit and a second bit line, wherein a gate of said third transistor is connected to said first word line, and
a fourth transistor configured to be connected between said third transistor and said second bit line, wherein a gate of said fourth transistor is connected to said first column selecting line.
wherein said first bit line and said second bit line are set as a pair.

16. The method for operating a semiconductor memory device according to claim 12, wherein each of said plurality of column selecting lines is provided between two adjacent memory cells of said plurality of memory cells, and
said step (b) includes:
(b2) supplying a column selecting signal to each of said two adjacent memory cells through said selected one column selecting line.

17. The method for operating a semiconductor memory device according to claim 12, wherein said semiconductor memory device further including:
a first logic circuit; and
a second logic circuit,
said step (a) includes:
(a1) selecting one of said plurality of word lines based on a row address and a column address by said first logic circuit, and
(a2) selecting one of said plurality of column selecting lines based on said row address and said column address by said second logic circuit,
said step (b) includes:
(b1) outputting a word signal to said selected one of the plurality of word lines based on said row address and said column address by said first logic circuit, and
(b2) outputting a column selecting signal to said second logic circuit based on said row address and said column address by said second logic circuit.
